(19) United States
(12) Patent Application Publication
(10) Pub. No.: US 2010/0037005 A1
(43) Pub. Date: Feb. 11, 2010

(54) COMPUTING SYSTEM INCLUDING PHASE-CHANGE MEMORY

(76) Inventors: Jin-kyu KIM, Seoul (KR); Kyoung-il BANG, Yongin-gun (KR); Hyung-gyu LEE, Seoul (KR)

Correspondence Address: North Star Intellectual Property Law, PC, P.O. Box 34688, Washington DC, DC, 20043, US

(21) Appl. No.: 12/437,037

(22) Filed: May 7, 2009

(30) Foreign Application Priority Data
Aug. 5, 2008 (KR) 10-2008-076666

(51) Int. Cl. G06F 12/02; G11C 11/00; G06F 12/00

(52) U.S. Cl. 711/103; 365/163; 711/E12.001; 711/E12.008

(57) ABSTRACT

A computing system, more particularly, a computing system including a phase-change memory is provided. The computing system includes a flash memory configured to store data and a phase-change memory configured to store address mapping information for converting a logical address into a physical address. The phase-change memory is configured to store the address mapping information while the computing system is in a power-off state. The computing system may store an address mapping table to manage the flash memory in the phase-change memory.

### CROSS-REFERENCE TO RELATED APPLICATION(S)

This application claims the benefit under 35 U.S.C. §119(a) of Korean Patent Application No. 10-2008-0076666, filed on Aug. 5, 2008 in the Korean Intellectual Property Office, the disclosure of which is incorporated herein in its entirety by reference.

### BACKGROUND

1. Field

The following description relates to a computing system, and more particularly, to a computing system including a phase-change memory.

2. Description of the Related Art

non-volatile, large-capacity semiconductor memory devices have become widespread. An example of such semiconductor devices is a flash memory which might be used in a portable electrical device. Flash memories are commonly used in embedded systems, mobile systems, and the like, as they are non-volatile and have high access speed and low power consumption.

However, flash memories have one limitation not present in hard disks. In order to overwrite data on a flash memory, data written on the flash memory is first erased. This process is called “erase-before-write”. That is, the flash memory should be initialized to an erased state before writing data thereon.

However, an erase operation of a flash memory requires a longer period of time compared to a write operation. Additionally, flash memory may perform an erase operation in larger blocks than in a write operation. Accordingly, parts that need not to be erased may be incidentally erased during an erase operation. The incidentally erased parts are then restored by write operation.

As such, since in flash memories, the speed at which a write operation is performed is lower than the speed at which a read operation is performed, if a flash memory performs the erase operation more than, for example, about one hundred thousand times on the same block, the flash memory can be no longer used. Accordingly, the flash memory performs “wear leveling” in order to prevent the erase operation from being excessively repeatedly performed on specific blocks.

A Flash Translation Layer (FTL) is software for solving certain problems of flash memories and effectively managing flash memories. The FTL receives a logical address (LA) from a file system and converts the LA to a physical address (PA). The LA is an address identified by the file system and the PA is an address identified by a flash memory.

The FTL refers to an address mapping table in order to manage address mapping. The address mapping table stores logical addresses and their corresponding physical addresses. The size of the address mapping table may depend on the size of a mapping unit. Mapping methods may include, for example, a page mapping method, a block mapping method, or a hybrid mapping method.

The page mapping method uses a page address mapping table. The page address mapping table is used to perform mapping in units of pages and to store the correlation between logical pages and their corresponding physical pages. The block mapping method uses a block address mapping table. The block address mapping table is used to perform mapping in units of blocks and to store logical blocks and their corresponding physical blocks. The hybrid mapping method is a combination of the page mapping method and block mapping method.

Generally, a memory block consists of dozens of or hundreds of pages. Accordingly, in the page mapping method, the size of the address mapping table is several tens or hundreds times larger than that used in the block mapping method. That is, the page mapping method uses a larger memory space for the address mapping table.

Since the block mapping method performs mapping in units of blocks, the size of the address mapping table may be reduced in comparison to the page mapping method. However, according to the block mapping method, since the locations of pages that are to be written in blocks are fixed, many merge operations are generally performed. The merge operation collects only valid pages in memory blocks and assigns the valid pages to new memory blocks.

The hybrid mapping method applies the page mapping method to log blocks and the block mapping method to data blocks. The hybrid mapping method may reduce both the number of merge operations and the size of an address mapping table, by using operations of both the page mapping method and block mapping method.

Generally, an address mapping table is driven on a volatile random access memory (RAM), as volatile RAMs typically operate at higher speeds than flash memories. However, data stored in volatile RAM is lost when its power feed is stopped. Accordingly, the address mapping table may be stored in a flash memory. As a result, mapping data stored in the volatile RAM and flash memory may be changed whenever the correlation between the physical addresses and logical addresses is changed, although this may result in performance deterioration of a computing system. Also, mapping data stored in the volatile RAM may not match with mapping data stored in the flash memory, resulting in reliability deterioration of a computing system.

### SUMMARY

In one general aspect, a computing system includes a flash memory configured to store data and a phase-change memory configured to store address mapping information for converting a logical address into a physical address, wherein the phase-change memory is configured to store the address mapping information while the computing system is in a power-off state.

The address mapping information may include a correlation between the logical address and the physical address. The computing system may include a processor configured to convert the logical address into the physical address using the address mapping information. The processor may further be configured to transfer the physical address to the flash memory, and the flash memory may be configured to output data corresponding to the physical address. The processor may also be configured to update the address mapping information in response to the flash memory outputting the data. The processor may additionally be configured to update the address mapping information in response to the correlation between the logical address and the physical address being changed.

The address mapping information may further include memory block information configured to indicate the number of valid pages in a memory block or indicate whether the memory block is a bad block. The address mapping information may further include physical page information configured to indicate validity or invalidity of data stored in each physical page. The address mapping information may further include information configured to indicate the number of write operations performed on each physical page. The processor may be configured to determine whether data stored in each physical data is hot data or cold data, based on the number of write operations.

The phase-change memory may include a memory cell array of a plurality of phase-change memory cells. Each phase-change memory cell may include a memory element constructed of a variable resistance material and a selection element configured to select a memory cell. The selection element may be a diode connected between the memory element and a word line. The flash memory may be a NAND flash memory.

The computing system stores an address mapping table for managing a flash memory in a phase-change memory. Therefore, it is possible to enhance the speed, reliability, lifetime, etc. of a computing system.

Other features and aspects will be apparent from the following detailed description, the drawings, and the claims.

### BRIEF DESCRIPTION OF THE DRAWINGS

FIGS. 1 and 2 are diagrams illustrating exemplary memory cells of phase-change memories.

FIG. 3 is a graph illustrating exemplary characteristics of variable resistance materials (GSTs) illustrated in FIGS. 1 and 2.

FIG. 4 is a diagram illustrating an exemplary computing system.

FIG. 5 is a diagram illustrating an exemplary software structure of a computing system.

FIG. 6 is a diagram illustrating an exemplary method for converting logical addresses into physical addresses using an address mapping table.

FIG. 7 is a flowchart illustrating an exemplary method for storing data in a flash memory.

FIG. 8 is a diagram illustrating an exemplary computing system.

FIG. 9 is a diagram illustrating an exemplary structure of metadata illustrated in FIG. 8.

FIG. 10 is a flowchart illustrating an exemplary method for erasing data stored in a flash memory.

FIG. 11 is a diagram illustrating an exemplary structure of a Solid State Drive (SSD) system including a phase-change memory.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses, and/or methods described herein will be suggested to those of ordinary skill in the art. Also, descriptions of well-known functions and constructions may be omitted for increased clarity and conciseness.

In a computing system according to one example, management information for managing a flash memory is stored in a phase-change memory. The phase-change memory supports byte-unit access. Since such a phase-change memory is non-volatile, data stored therein can be maintained even when power is no longer supplied. The phase-change memory, which may be constructed of chalcogenide alloys, is a large-capacity memory which can be manufactured at low costs by a simple manufacturing process.

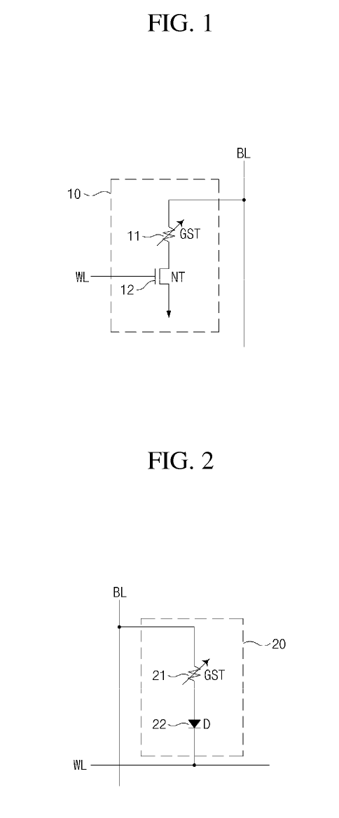

FIGS. 1 and 2 are diagrams illustrating exemplary memory cells 10 and 20 of phase-change memories. Referring to FIG. 1, the memory cell 10 includes a memory element 11 and a selection element 12. The memory element 11 is connected between a bit line BL and the selection element 12, and the selection element 12 is connected between the memory element 11 and a ground.

The memory element 11 is constructed of a variable resistance material. The variable resistance material may be Ge—Sb—Te (GST) with variable resistance depending on temperature. The GST has one of two stable states, that is, a crystal state and amorphous state, depending on temperature. The GST changes to the crystal state or amorphous state according to current supplied through the bit line BL. A phase-change memory stores data using the variable resistance of the GST.

The selection element 12 may be a NMOS transistor NT. The gate of the NMOS transistor NT is connected to a word line WL. If a predetermined voltage is applied to the word line WL, the NMOS transistor NT is turned on. If the NMOS transistor NT is turned on, current flows to the memory element 11 through the bit line BL. In FIG. 1, the memory element 11 is connected between the bit line BL and the selection element 12. However, the selection element 12 may also be connected between the bit line BL and memory element 11.

Referring to FIG. 2, the memory cell 20 includes a memory element 21 and a selection element 22. The memory element 21 is connected between a bit line BL and the selection element 22, and the selection element 22 is connected between the memory element 21 and a ground. The memory element 21 may be the same element as the memory element 11 illustrated in FIG. 1.

The selection element 22 may be a diode D. The anode of the diode D is connected to the memory element 21, and the cathode of the diode D is connected to a word line WL.

If the voltage difference between the anode and cathode of the diode D exceeds a threshold voltage of the diode D, the diode D is turned on. If the diode D is turned on, current flows to the memory element 21 through the bit line BL.

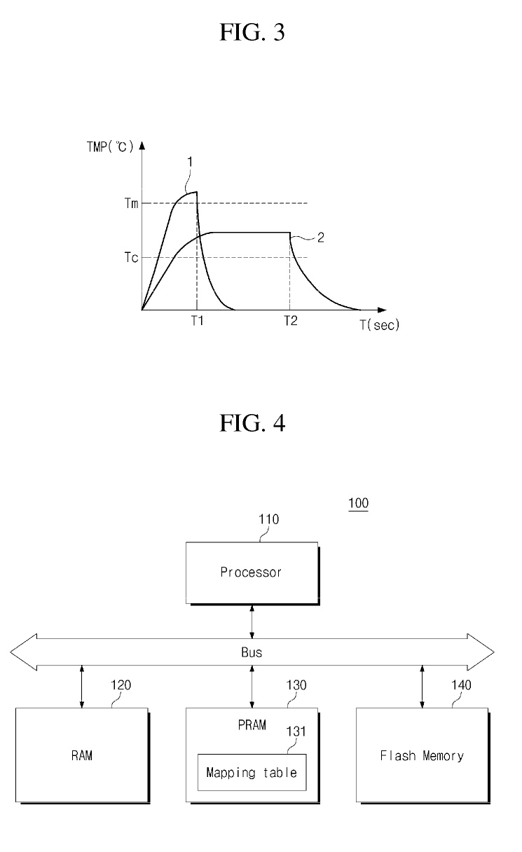

FIG. 3 is a graph illustrating exemplary characteristics of the variable resistance materials (GSTs) illustrated in FIGS. 1 and 2. In FIG. 3, a reference number 1 represents a condition under which the GST is in an amorphous state, and a reference number 2 represents a condition under which the GST is in a crystal state.

The GST enters the amorphous state when heated to a temperature higher than a melting temperature Tm and then removing the heat. The amorphous state is commonly referred to as a “reset state”, and stores data “1”. A phase-change memory provides reset current to the GST to program to a reset state.

The GST enters the crystal state when heated for a time period T2, longer than a time period T1, at temperature higher than a crystallization temperature Tc and lower than the melting temperature Tm, and gradually cooling the GST. The crystal state is referred to as a “set state” and stores data “0”. The phase-change memory provides set current to the GST to program to a set state.

FIG. 4 is a diagram illustrating an exemplary computing system 100. Referring to FIG. 4, the computing system 100 includes a processor 110, a volatile RAM 120, a phase-change memory 130, and a flash memory 140.

The flash memory 140 includes a plurality of memory cells having a string structure. A group of memory cells is commonly called a cell array. A cell array of the flash memory includes a plurality of memory blocks, each memory block includes a plurality of pages, and each page includes a plurality of memory cells sharing the same word line.

In the flash memory 140, erase operations are performed in different units from read operations and write operations. The flash memory 140 performs erase operations in units of memory blocks, while read operations and program operations are performed in units of pages. Also, since the flash memory 140 may not support overwrite, the flash memory 140 may perform an erase operation before a program operation.

Due to certain characteristics of the flash memory 140, read, write, and erase operations may be managed separately in order to use the flash memory 140 in place of a hard disk. A Flash Translation Layer (FTL) is system software developed for such separate management.

The phase-change memory 130 stores an address mapping table 131. The address mapping table 131 stores the correlation between logical addresses and physical addresses. As described above, the logical addresses may be used by a file system, while the physical addresses may be used by the flash memory 140.

The volatile RAM 120 may be used as a main memory. The file system may be loaded in the volatile random access memory 120, and then processed by the processor 110.

The processor 110 controls the entire operations of the computing system 100 according to one example. As described above, the processor 110 may process data loaded in the volatile RAM 120. Also, the processor 110 accesses the flash memory 140 with reference to the address mapping table 131 stored in the phase-change memory 130. The processor 110 converts a logical address received from the file system into a physical address with reference to the address mapping table 131 stored in the phase-change memory 130. Since the phase-change memory 130 supports byte-unit access and its operating speed is high, the processor 110 can convert the logical address into the physical address without having to use the volatile RAM 120.

The processor 110 applies the physical address to the flash memory 140. The flash memory 140 outputs data corresponding to the received physical address, which is processed by the processor 110. The processed data is stored temporarily in the volatile RAM 120 or stored permanently in the flash memory 140.

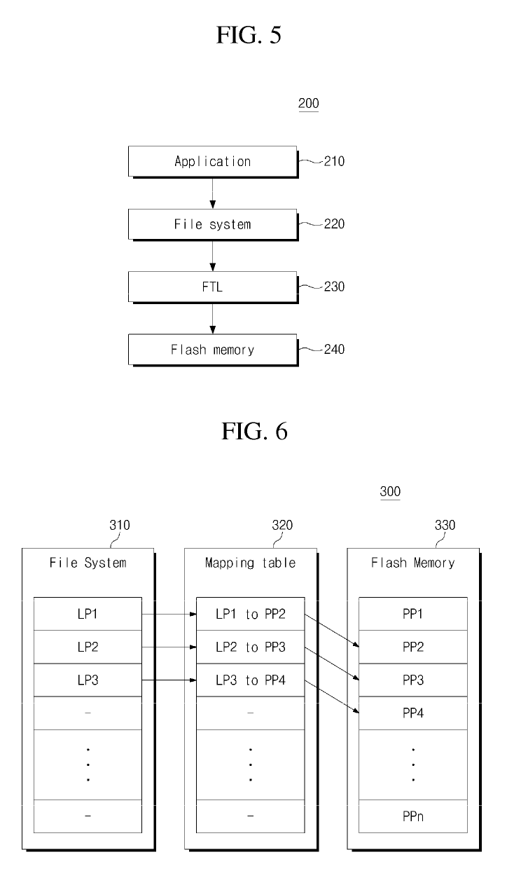

FIG. 5 is a diagram illustrating an exemplary a software structure of a computing system 200. Referring to FIG. 5, the computing system 200 has a software layer structure which includes an application 210, a file system 220, a flash translation layer (FTL) 230 and a flash memory 40 in this order.

The application 210 is software for processing data in response to a user's input. As one example, the application 210 may be document processing software such as a word processor, calculation software such as a spreadsheet, or document viewing software such as a web browser. The file system 220 is a structure or software used to store data. The file system 220 may be a File Allocation Table (FAT), NTFS, or similar file system.

The FTL 230 receives a logical address LA from the application 210 or file system 220, and converts the logical address LA into a physical address PA. The physical address PA is provided to the flash memory 140 (see FIG. 4). The FTL 230 has an address mapping table for address conversion, the address mapping table stored in the phase-change memory 130 shown in FIG. 4.

FIG. 6 is a diagram illustrating an exemplary method for converting logical addresses into physical addresses using the address mapping table. As one example, a page mapping method is used; however, various mapping methods, such as a block mapping method or a hybrid mapping method, may be used.

Referring to FIG. 6, a file system 310 transfers to the processor 110 (see FIG. 4) logical page numbers LP corresponding to data that is to be accessed. In FIG. 6, the file system 310 transfers logical page numbers LP1, LP2 and LP3 to the processor 110.

The processor 110 converts the logical page numbers LP1, LP2 and LP3 into physical page numbers, with reference to the address mapping table 320 stored in the phase-change memory 130 (see FIG. 4). The address mapping table 320 stores the correlation between logical pages and physical pages. Referring to FIG. 6, the first logical page (LP1) corresponds to a second physical page (PP2), the second logical page (LP2) corresponds to a third physical page (PP3), and the third logical page (LP3) corresponds to a fourth physical page (PP4), respectively.

The processor 110 transfers the physical page numbers PP2, PP3 and PP4 to the flash memory 330. Referring to FIG. 6, the processor 110 transfers the physical page numbers PP2, PP3 and PP4 to the flash memory 330. The flash memory 330 outputs data corresponding to the physical page numbers PP2, PP3 and PP4.

The address conversion operation according to one example is performed as described above. According to another example, the address mapping table is stored in a phase-change memory. Since a phase-change memory supports byte-unit access, the phase-change memory has higher speed than a flash memory when inputting or outputting a small amount of data. Accordingly, in the case of storing the address mapping table in the phase-change memory, a period of time consumed for the address conversion operation may be reduced. Also, since phase-change memory is non-volatile, the phase-change memory can maintain data when power is no longer supplied to the phase-change memory. Accordingly, the phase-change memory can maintain mapping information even when power is no longer supplied.

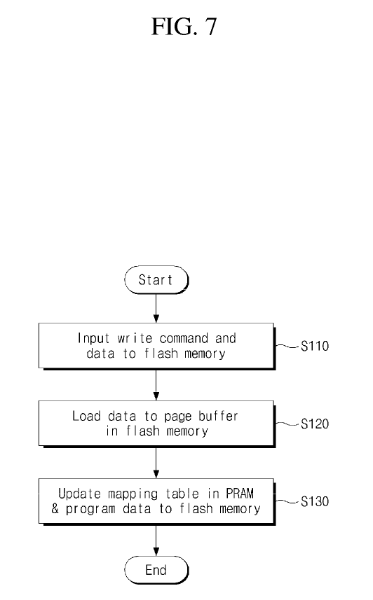

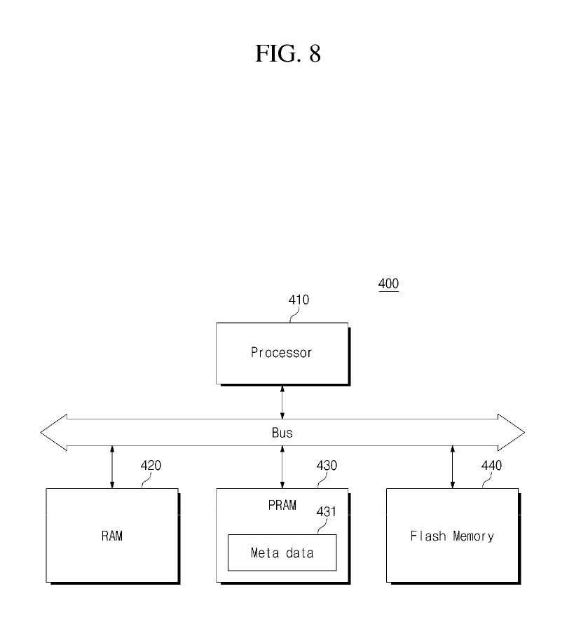

FIG. 7 is a flowchart illustrating an exemplary method for storing data in the flash memory 140 (see FIG. 4). In one example, while data is stored in the flash memory 140, the processor 110 (see FIG. 4) is in an idle state. Accordingly, the address mapping table 131 stored in the phase-change memory 130 may be updated by the processor 110. As a result, a period of time consumed for programming is reduced.

Referring to FIG. 7, in operation S110, a write command and data are input to the flash memory 140. A file system transfers a write command and data to the flash memory 140 in response to a write request from an application.

In operation S120, the write data is loaded in a page buffer (not shown) of the flash memory 140 in units of pages. The page buffer is connected to a plurality of bit lines, and a supply voltage VCC or a ground voltage 0V is applied to the respective bit lines according to the data loaded in the page buffer. Memory cells connected to bit lines to which the voltage VCC is applied are not programmed, and memory cells connected to bit lines to which the ground voltage 0V is applied are programmed.

While the data loaded in the page buffer is stored in the memory cells, the address mapping table 131 stored in the phase-change memory 130 (see FIG. 4) is updated. As one example, the correlation between the logical addresses and physical addresses for the stored data is stored in the address mapping table 131. As described above, since the address mapping table 131 stored in the phase-change memory 130 is updated while the data loaded in the page buffer is stored in the memory cells, a period of time consumed for programming is reduced.

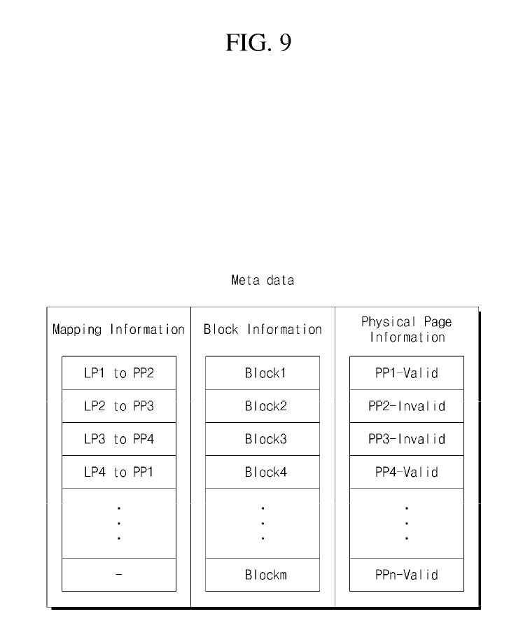

FIG. 8 is a diagram illustrating an exemplary computing system. As one example, a phase-change memory 430 stores both data for management of a flash memory and an address mapping table. Data for management of a flash memory may be referred to as metadata. As shown in FIG. 8, the phase-change memory 430 stores metadata 431. The metadata 431 includes management information for managing the flash memory 440. As one example, the metadata 431 may include mapping information, memory block information, and physical page information, among other types of information. The processor 410 may manage the flash memory 440 with reference to the metadata 431. Hereinafter, the structure of the metadata 431 will be described with reference to FIG. 9.

FIG. 9 is a diagram illustrating an exemplary structure of the metadata illustrated in FIG. 8. Referring to FIG. 9, the metadata includes mapping information, memory block information, and physical page information.

The mapping information defines a correlation between logical addresses and physical addresses. As shown in FIG. 9, in the mapping information, a first logical page LP1 corresponds to a second physical page PP2, a second logical page LP2 corresponds to a third physical page PP3, a third logical page LP3 corresponds to a fourth physical page PP4, and a fourth logical page LP4 corresponds to a first physical page PP1. The processor 410 (see FIG. 8) converts logical addresses into physical addresses, with reference to the mapping information. The memory block information includes information about the number of valid pages in memory blocks, the presence or absence of bad block in the memory blocks, and similar information. The physical page information includes information about the validity of data stored in each page. The processor 410 can determine the validity of a page based on the physical page information. Referring to FIG. 9, the physical page information indicates that the first physical page PP1 is valid and the second physical page PP2 is invalid.

The processor 410 can efficiently manage the flash memory 440 with reference to the metadata. As one example, the processor 410 can determine whether stored data is “hot data” or “cold data”, based on the number of writing operations performed on the corresponding physical page. “Hot data” is data which is updated relatively often, and “cold data” is data which is updated relatively rarely. Determining hot data and cold data is useful to select an optimal method upon storing or merging of data.

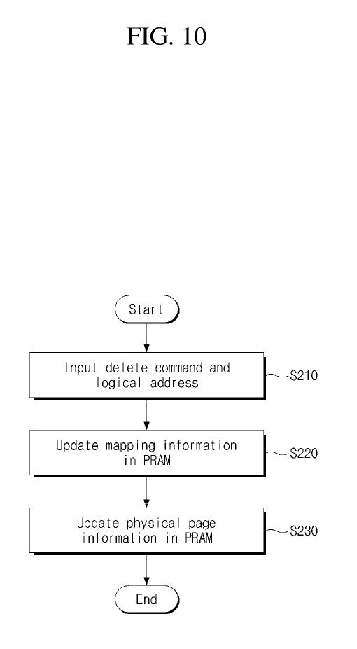

FIG. 10 is a flowchart illustrating an exemplary method for erasing data stored in a flash memory. In one example, erase operations are performed by updating mapping information for logical pages that are requested to be erased and invalidating physical pages. That is, data stored in the flash memory is not actually erased.

Referring to FIG. 10, in operation S210, a file system generates an erase command and a logical address. In operation S220, mapping information stored in a phase-change memory is updated. By updating the mapping information, the logical address of data that is requested to be erased no longer corresponds to its original physical address. In operation S230, physical page information stored in the phase-change memory is updated. By updating the physical page information, a physical page corresponding to the data that is requested to be erased is invalidated. Since the phase-change memory allows byte-unit access, these operations may be performed in a relatively short period of time.

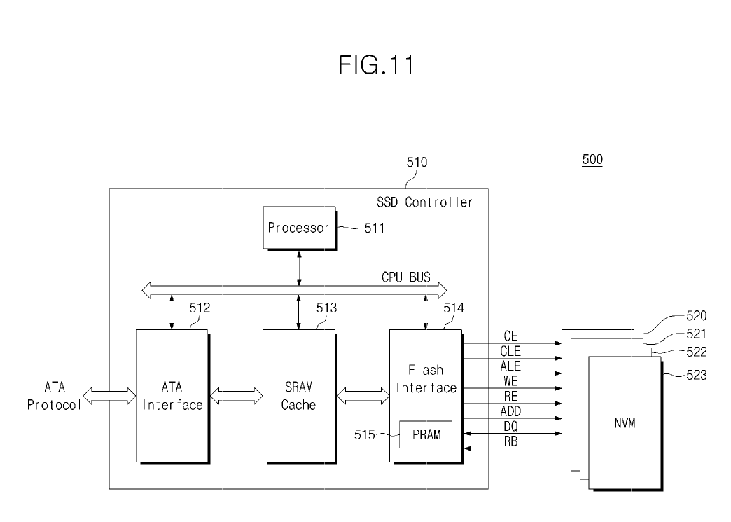

FIG. 11 is a diagram illustrating an exemplary structure of a Solid State Drive (SSD) system 500 including a phase-change memory. Referring to FIG. 11, the SSD system 500 includes a SSD controller 510 and a plurality of flash memories 520 through 523.

The computing systems 100 and 200 according to above-described examples may be applied to the SSD system 500. A SSD is a data storage using memory chips such as flash memories to store data, instead of a rotating plate which is used in a typical hard disk drive. The SSD has higher operation speed, excellent impact resistivity, and low power consumption, compared to a hard disc drive, which operates mechanically.

Again returning to FIG. 11, a processor 511 receives a command from a host, and determines and controls whether to store data from the host in a flash memory or to read data stored in the flash memory and transmit it to the host, according to the command. An ATA interface 512 exchanges data with the host under the control of the processor 511. The ATA interface 512 patches a command and address from the host and transfers them to the processor 511 via a CPU bus. Data received from or transmitted to the host through the ATA interface 512 is transferred through a SRAM cache 513 not via CPU bus, under the control of the processor 511.

The SRAM cache 513 temporarily stores data that are transmitted between the host and flash memories 520 through 523. Also, the SARM cache 513 is used to store program that is to be operated by the process 511. The SRAM cache 513 can be considered as a kind of buffer memory and may be any other memory. The flash interface 514 exchanges data with nonvolatile memories that are used as storage. The flash interface 514 may be designed to support NAND flash memories, One-NAND flash memories, or multi-level flash memories. The flash interface 514 includes a phase-change memory 515 according to an embodiment. As described above, the phase-change memory 515 stores metadata.

The semiconductor computing system according to the above examples may be used as a mobile storage device. Accordingly, the semiconductor computing system may be used as storage for a MP3, digital camera, PDA, e-Book, and the like. Also, the semiconductor computing system may be used as storage for a digital TV, computer, and the like.

As described above, the computing system according to the above examples stores management information for managing a flash memory in a phase-change memory. Generally, a phase-change memory has higher operating speed than flash memories and has non-volatile characteristics differently from volatile RAMs. Since the management information is stored in a phase-change memory instead of a flash memory and volatile RAM, the computing system has relatively higher operating speed and the problem of data mismatch caused in the case of storing data respectively in a volatile RAM and a flash memory is avoided.

The methods described above may be recorded, stored, or fixed in one or more computer-readable media that includes program instructions to be implemented by a computer to cause a processor to execute or perform the program instructions. The media may also include, alone or in combination with the program instructions, data files, data structures, and the like. Examples of computer-readable media include magnetic media, such as hard disks, floppy disks, and magnetic tape; optical media such as CD ROM disks and DVDs; magneto-optical media, such as optical disks; and hardware devices that are specially configured to store and perform program instructions, such as read-only memory (ROM), random access memory (RAM), flash memory, and the like. Examples of program instructions include machine code, such as produced by a compiler, and files containing higher level code that may be executed by the computer using an interpreter. The described hardware devices may be configured to act as one or more software modules in order to perform the operations and methods described above, or vice versa.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A computing system comprising:
a flash memory configured to store data; and
a phase-change memory configured to store address mapping information for converting a logical address into a physical address,
wherein the phase-change memory is configured to store the address mapping information while the computing system is in a power-off state.

2. The computing system of claim 1, wherein the address mapping information includes a correlation between the logical address and the physical address.

3. The computing system of claim 2, further comprising a processor configured to convert the logical address into the physical address using the address mapping information.

4. The computing system of claim 3, wherein the processor is configured to transfer the physical address to the flash memory, and the flash memory is configured to output data corresponding to the physical address.

5. The computing system of claim 4, wherein the processor is configured to update the address mapping information in response to the flash memory outputting the data.

6. The computing system of claim 4, wherein the processor is configured to update the address mapping information in response to the correlation between the logical address and the physical address being changed.

7. The computing system of claim 1, wherein the address mapping information further comprises memory block information configured to indicate the number of valid pages in a memory block or indicate whether the memory block is a bad block.

8. The computing system of claim 1, wherein the address mapping information further comprises physical page information configured to indicate validity or invalidity of data stored in each physical page.

9. The computing system of claim 1, wherein the address mapping information further comprises information configured to indicate the number of write operations performed on each physical page.

10. The computing system of claim 9, wherein the processor is configured to determine whether data stored in each physical data is hot data or cold data, based on the number of write operations.

11. The computing system of claim 1, wherein the phase-change memory comprises a memory cell array of a plurality of phase-change memory cells.

12. The computing system of claim 11, wherein each phase-change memory cell comprises:
a memory element constructed of a variable resistance material; and
a selection element configured to select a memory cell.

13. The computing system of claim 12, wherein the selection element is a diode connected between the memory element and a word line.

14. The computing system of claim 1, wherein the flash memory is a NAND flash memory.
